(19) United States
(12) Patent Application Publication
(10) Pub. No.: US 2026/0114173 A1
(43) Pub. Date: Apr. 23, 2026

(54) DISPLAY DEVICE AND METHOD OF FABRICATING THE SAME

(71) Applicant: Samsung Display Co., LTD., Yongin-si (KR)

(72) Inventor: Hyun Eok SHIN, Yongin-si (KR)

(21) Appl. No.: 19/240,407

(22) Filed: Jun. 17, 2025

(30) Foreign Application Priority Data
Oct. 22, 2024 (KR) 10-2024-0144543

(51) Int. Cl. H10K 71/40; H10K 50/15; H10K 50/17; H10K 71/12; H10K 71/20; H10K 102/00

(52) U.S. Cl. CPC H10K 71/40; H10K 50/15; H10K 50/17; H10K 71/12; H10K 71/20; H10K 2102/361

(57) ABSTRACT

A display device includes: a substrate on which an emission area and a non-emission area are defined; a first anode electrode positioned on the substrate in the emission area; a pixel defining layer positioned on the substrate in the non-emission area, defining an opening, and covering an edge of the first anode electrode; a hole layer positioned on the first anode electrode; a first organic light emitting layer positioned on the hole layer; an electron layer positioned on the first organic light emitting layer; a cathode electrode positioned on the electron layer, where the hole layer includes a side surface facing the non-emission area, and an inclination angle formed by the side surface of the hole layer and the pixel defining layer is in a range of about 60° to about 90°.

This application claims priority to Korean Patent Application No. 10-2024-0144543, filed on Oct. 22, 2024, and all the benefits accruing therefrom under 35 U.S.C. § 119, the content of which in its entirety is herein incorporated by reference.

### BACKGROUND

### 1. Field

The present disclosure relates to a display device and a method of fabricating the same.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display devices may be flat panel display devices such as liquid crystal display devices, field emission display devices, or organic light emitting display devices. Among such flat panel display devices, a light emitting display device may display an image without a backlight unit for providing light to a display panel because each of pixels of the display panel includes light emitting elements that may emit light by themselves.

Recently, as various electronic devices develop, the demand for high-resolution display devices has increased. Since the high-resolution display device typically has a high degree of integration of pixels, an interval between light emitting elements overlapping respective emission areas may be reduced. Accordingly, the high-resolution display device may be formed using a pattern process of forming individual pixels rather than a mask process.

### SUMMARY

Embodiments of the present disclosure provide an ultrahigh-resolution display device.

Embodiments of the present disclosure also solve a material reliability defect due to a high temperature process.

Embodiments of the present disclosure also solve a reliability defect due to moisture included in a display device.

In an embodiment of the disclosure, a display device includes: a substrate on which an emission area and a non-emission area are defined; a first anode electrode positioned on the substrate in the emission area; a pixel defining layer positioned on the substrate in the non-emission area, defining an opening, and covering an edge of the first anode electrode; a hole layer positioned on the first anode electrode; a first organic light emitting layer positioned on the hole layer; an electron layer positioned on the first organic light emitting layer; a cathode electrode positioned on the electron layer, where the hole layer includes a side surface facing the non-emission area, and an inclination angle formed by the side surface of the hole layer and the pixel defining layer is in a range of about 60° to about 90°.

In an embodiment, the hole layer may include a conductive high-molecular material.

In an embodiment, the hole layer may include at least one selected from poly(3,4-ethylenedioxythiophene): poly(styrenesulfonate)(AI4083) (available from CLEVIOS-Heraeus GmbH), tris(4-carbazoyl-9-ylphenyl)amine (TCTA), 4,4′-bis(N-carbazolyl)-1,1′-biphenyl (CBP), 2,2′,2″(1,3,5-benzinetriyl)-tris(1-phenyl-1-H-benzimidazole) (TPBI), and bis[2-(2-pyridinyl-N)phenyl-C](acetylacetonato) iridium(III) (Ir(ppy)₂(acac).

In an embodiment, the hole layer may include a hole injection layer in contact with the first anode electrode, and a hole transporting layer positioned between the injection layer and the first organic light emitting layer, and an inclination angle formed by a side surface of the hole injection layer facing the non-emission area and the pixel defining layer is in the range of about 60° to about 90°.

In an embodiment, an inclination angle formed by a side surface of the hole layer facing the non-emission area and the hole injection layer may be in the range of about 60° to about 90°.

In an embodiment, an inclination angle formed by a side surface of the first organic light emitting layer facing the non-emission area and the hole transporting layer may be in the range of about 60° to about 90°.

In an embodiment, the electron layer may be in contact and with and covers the side surface of the hole injection layer facing the non-emission area, the side surface of the hole transporting layer facing the non-emission area, and the side surface of the first organic light emitting layer facing the non-emission area.

In an embodiment, the cathode electrode may cover the side surface of the hole injection layer facing the non-emission area, the side surface of the hole transporting layer facing the non-emission area, and the side surface of the first organic light emitting layer facing the non-emission area.

In an embodiment, the display device may further include a second anode electrode spaced apart from the first anode electrode with the pixel defining layer interposed therebetween; and a second organic light emitting layer positioned on the second anode electrode, where the hole layer overlapping the first organic light emitting layer and the hole layer overlapping the second organic light emitting layer are spaced apart from each other with the pixel defining layer interposed therebetween.

In an embodiment, the electronic layer may be in contact with the first organic light emitting layer and the second organic light emitting layer, and the electronic layer in contact with the first organic light emitting layer and the electronic layer in contact with the second organic light emitting layer are integral with each other.

In an embodiment, the electronic layer may include a low-molecular material.

In an embodiment, the pixel defining layer may include a first surface facing the cathode electrode, the first surface includes: a first portion overlapping the first organic light emitting layer; a second portion overlapping the second organic light emitting layer; and a third portion positioned between the first portion and the second portion, and the third portion is covered by the electronic layer.

In an embodiment, the third portion may be in entire contact with the electronic layer.

In an embodiment of the disclosure, a method of fabricating a display device, includes entirely coating a hole injection layer, a hole transporting layer, and an organic light emitting layer on a substrate including an anode electrode and a pixel defining layer; removing portions of the hole injection layer, the hole transporting layer, and the organic light emitting layer by a photo pattern process; removing moisture by performing a heat treatment at a temperature of about 150° C. or higher in a vacuum environment; and entirely depositing an electronic layer and a cathode electrode on the organic light emitting layer.

In an embodiment, in the entire coating of the hole injection layer, the hole transporting layer, and the organic light emitting layer on the substrate including the anode electrode and the pixel defining layer, each of the hole injection layer and the hole transporting layer may include a conductive high-molecular material, and the hole injection layer, the hole transporting layer, and the organic light emitting layer may be exposed to the air.

In an embodiment, in the removing of the portions of the hole injection layer, the hole transporting layer, and the organic light emitting layer by the photo pattern process, the hole injection layer, the hole transporting layer, and the organic light emitting layer may be simultaneously removed by a dry etching process, and an inclination angle formed by the pixel defining layer and a side surface of the hole injection layer may be in a range of about 60° to about 90°.

In an embodiment, in the entire depositing of the electronic layer and the cathode electrode on the organic light emitting layer, the electron layer and the cathode electrode may be deposited in a vacuum chamber, and the electron layer includes a low-molecular material.

In an embodiment of the disclosure, an electronic device includes: a display device including: a substrate on which an emission area and a non-emission area are defined; a first anode electrode positioned on the substrate in the emission area; a pixel defining layer positioned on the substrate in the non-emission area, defining an opening, and covering an edge of the first anode electrode; a hole layer positioned on the first anode electrode; a first organic light emitting layer positioned on the hole layer; an electron layer positioned on the first organic light emitting layer; a cathode electrode positioned on the electron layer, where the hole layer includes a side surface facing the non-emission area, and an inclination angle formed by the side surface of the hole layer and the pixel defining layer is in a range of about 60° to about 90°.

With a display device and a method of fabricating the display device according to an embodiment, an ultrahigh-resolution display device may be provided.

With the display device and the method of fabricating the display device according to an embodiment, a material reliability defect due to a high temperature process may be solved.

With the display device and the method of fabricating the display device according to an embodiment, a reliability defect due to moisture included in the display device may be solved.

### BRIEF DESCRIPTION OF THE DRAWINGS

The above and other features of embodiments of the present disclosure will become more apparent by describing in detail embodiments thereof with reference to the accompanying drawings, in which:

FIG. 1 is a perspective view illustrating an electronic device according to an embodiment;

FIG. 2 is a perspective view illustrating a display device included in the electronic device according to an embodiment;

FIG. 3 is a schematic cross-sectional view of the display device of FIG. 2;

FIG. 4 is a plan view illustrating an arrangement of a plurality of emission areas in a display area of FIG. 3;

FIG. 5 is a schematic cross-sectional view of a display layer taken along line X1-X1′ of FIG. 4;

FIG. 6 is an enlarged cross-sectional view of a display element layer overlapping a first emission area in FIG. 5;

FIG. 7 is an enlarged cross-sectional view of area ‘E’ in FIG. 6;

FIG. 8 is a schematic enlarged cross-sectional view of the display element layer overlapping a non-emission area positioned between the first emission area and a second emission area in FIG. 5;

FIG. 9 is a flowchart illustrating a method of fabricating the display element layer according to an embodiment;

FIGS. 10 and 11 are cross-sectional views illustrating S100 of FIG. 9;

FIGS. 12 to 15 are cross-sectional views illustrating S200 of FIG. 9;

FIG. 16 is a cross-sectional view illustrating S300 of FIG. 9; and

FIG. 17 is a cross-sectional view illustrating S400 of FIG. 9.

FIG. 18 is a block diagram of an electronic device according to one embodiment of the present disclosure.

FIG. 19 is a schematic diagram of an electronic device according to various embodiments of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it may be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, if the device in one of the drawing figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, the term such as “about” may mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments will be described in detail with reference to the accompanying drawings.

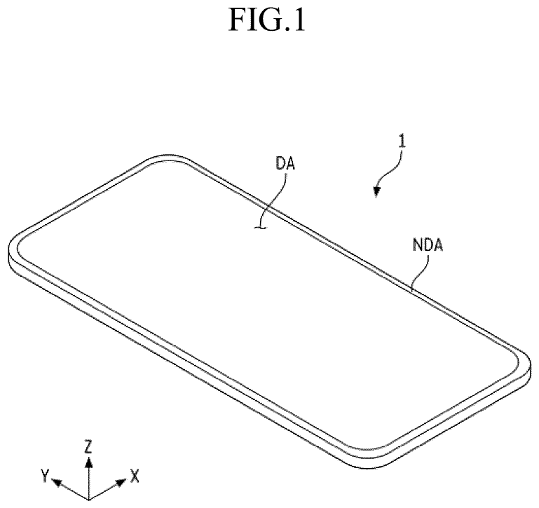

FIG. 1 is a schematic perspective view of an electronic device 1 according to an embodiment.

Referring to FIG. 1, an embodiment of the electronic device 1 displays a moving image or a still image. The electronic device 1 may refer to any electronic device that provides a display screen. For example, televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, and the like, that provide display screens, may be included in the electronic device 1.

In FIG. 1, a first direction (X-axis direction), a second direction (Y-axis direction), and a third direction (Z-axis direction) are defined. The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other. It may be understood that the first direction (X-axis direction) refers to a transverse direction in the drawings, the second direction (Y-axis direction) refers to a longitudinal direction in the drawings, and the third direction (Z-axis direction) refers to an upward and downward direction (i.e., a thickness direction) in the drawings. In the following specification, unless otherwise specified, the term “direction” may refer to both directions toward both sides extending along the direction. In addition, when both “directions” extending to both sides need to be distinguished from each other, one side will be referred to as “one side in the direction” and the other side will be referred to as “the other side in the direction”. In FIG. 1, a direction to which an arrow indicating a direction is directed will be referred to as one side in the direction, and a direction opposite to such a direction will be referred to as the other side in the direction.

Hereinafter, for convenience of description, in referring to surfaces of the electronic device 1 or respective members constituting the electronic device 1, one surface facing one side in a direction in which an image is displayed, that is, the third direction (Z-axis direction) will be referred to as an upper surface, and a surface opposite to the one surface will be referred to as the other surface. However, the present disclosure is not limited thereto, and the one surface and the other surface of the member may be referred to as a front surface and a rear surface, respectively, or be referred to as a first surface and a second surface, respectively. In addition, in describing relative positions of the respective members of the electronic device 1, one side in the third direction (Z-axis direction) may be referred to as an upper portion and the other side in the third direction (Z-axis direction) may be referred to as a lower portion.

A shape of the electronic device 1 may be variously modified. In an embodiment, for example, the electronic device 1 may have a shape such as a rectangular shape with a width greater than a length, a rectangular shape with a length greater than a width, a square shape, a quadrangular shape with rounded corners (vertices), other polygonal shapes, or a circular shape in a plan view or when viewed in the third direction (Z-axis direction).

In an embodiment, the electronic device 1 may include a display area DA and a non-display area NDA. The display area DA is an area where a screen may be displayed, and the non-display area NDA is an area where the screen is not displayed. The display area DA may also be referred to as an active area, and the non-display area NDA may also be referred to as a non-active area. The display area DA may occupy substantially the center of the electronic device 1.

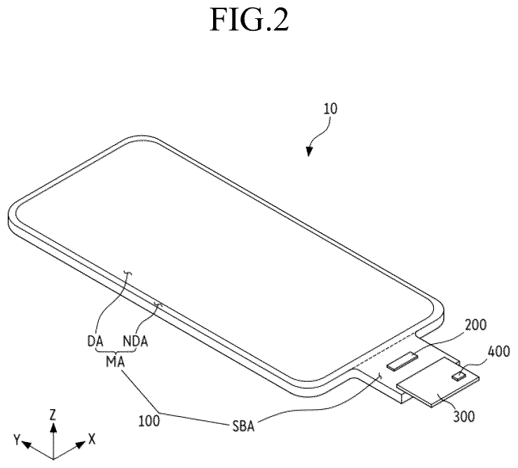

FIG. 2 is a perspective view illustrating a display device 10 included in the electronic device 1 according to an embodiment.

Referring to FIG. 2, the electronic device 1 according to an embodiment may include a display device 10. The display device 10 may provide a screen displayed on the electronic device 1. Examples of the display device 10 may include an inorganic light emitting diode display device, an organic light emitting display device, a quantum dot light emitting display device, a plasma display panel, a field emission display, and the like. Hereinafter, a case where an organic light emitting diode display device is applied as an example of the display device will be described by way of example, but the present disclosure is not limited thereto, and the same technical spirit may be applied to other display devices if applicable.

The display device 10 may have a shape similar to that of the electronic device 1 in a plan view. In an embodiment, for example, the display device 10 may have a shape similar to a rectangular shape, in a plan view, having short sides in the first direction (X-axis direction) and long sides in the second direction (Y-axis direction). A corner where the short side in the first direction (X-axis direction) and the long side in the second direction (Y-axis direction) meet may be rounded with a curvature, but is not limited thereto, and may also be right-angled. The planar shape of the display device 10 is not limited to the rectangular shape, and may be a shape similar to other polygonal shapes, a circular shape, or an elliptical shape.

In an embodiment, the display device 10 may include a display panel 100, a display driver 200, a circuit board 300, and a touch driver 400.

The display panel 100 may include a main area MA and a sub-area SBA. The main area MA may include a display area DA including pixels displaying an image and a non-display area NDA disposed around the display area DA.

The display area DA may emit light from a plurality of emission areas or a plurality of openings to be described later. In an embodiment, for example, the display panel 100 may include pixel circuits including switching elements, a pixel defining layer defining the emission areas or the openings, and self-light emitting elements. In an embodiment, for example, the self-light emitting element may include at least one selected from an organic light emitting diode (LED) including an organic light emitting layer, a quantum dot LED including a quantum dot light emitting layer, an inorganic LED including an inorganic semiconductor, and a micro LED, but is not limited thereto. In an embodiment, for example, the self-light emitting element is an organic light emitting diode, as illustrated in the drawings.

The non-display area NDA may be an area outside the display area DA. The non-display area NDA may be defined as an edge area of the main area MA of the display panel 100.

The sub-area SBA may be an area extending from one side of the main area MA. The sub-area SBA may include a flexible material that may be bent, folded, and rolled. In an embodiment, for example, when the sub-area SBA is bent, the sub-area SBA may overlap the main area MA in a thickness direction (e.g., the third direction (Z-axis direction)). The sub-area SBA may include the display driver 200 and pad portions connected to the circuit board 300. In another embodiment, the sub-area SBA may be omitted, and the display driver 200 and the pad portions may be positioned in the non-display area NDA.

The display driver 200 may output signals and voltages for driving the display panel 100. The display driver 200 may be formed as an integrated circuit (IC) and mounted on the display panel 100 in a chip on glass (COG) manner, a chip on plastic (COP) manner, or an ultrasonic bonding manner. In an embodiment, for example, the display driver 200 may be disposed in the sub-area SBA, and may overlap the main area MA in the thickness direction by bending of the sub-area SBA. In another embodiment, for example, the display driver 200 may be mounted on the circuit board 300.

The circuit board 300 may be attached onto the pad portions of the display panel 100 using an anisotropic conductive film (ACF). The circuit board 300 may be a flexible printed circuit board, a printed circuit board, or a flexible film such as a chip on film.

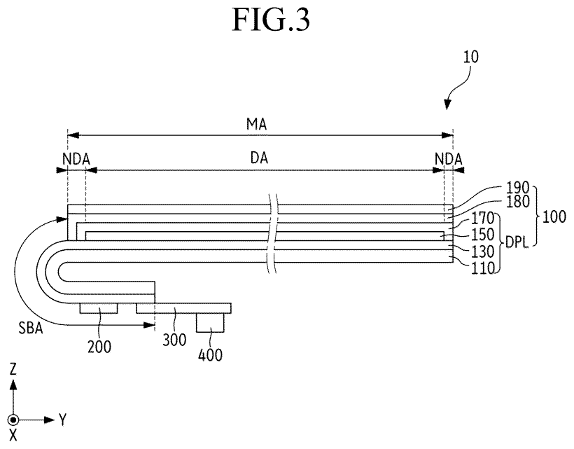

The touch driver 400 may be mounted on the circuit board 300. The touch driver 400 may be connected to a touch sensor layer 180 (see FIG. 3) of the display panel 100. The touch driver 400 may be formed as an integrated circuit.

FIG. 3 is a schematic cross-sectional view of the display device 10 of FIG. 2.

Referring to FIG. 3, an embodiment of the display panel 100 may include a display layer DPL, a touch sensor layer 180, and a color filter layer 190. The display layer DPL may include a substrate 110, a thin film transistor layer 130, a display element layer 150, and a thin film encapsulating layer 170.

The substrate 110 may be a base substrate or a base member. The substrate 110 may be a flexible substrate that may be bent, folded, and rolled. In an embodiment, for example, the substrate 110 may include a polymer resin such as polyimide (PI), but is not limited thereto. In another embodiment, the substrate 110 may include a glass material or a metal material.

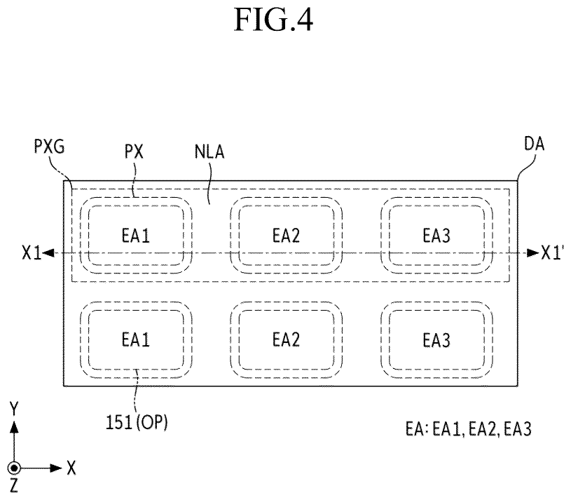

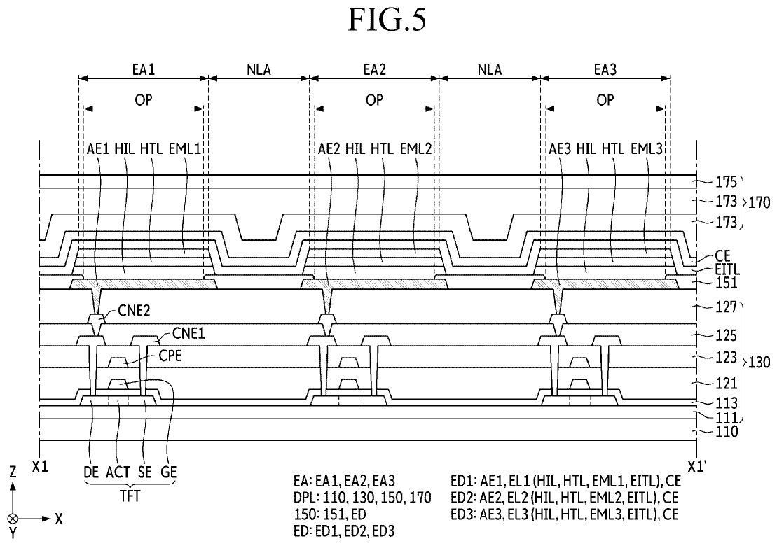

The thin film transistor layer 130 may be positioned on the substrate 110. The thin film transistor layer 130 may be positioned in the display area DA, the non-display area NDA, and the sub-area SBA. The thin film transistor layer 130 may include a plurality of thin film transistors TFT (see FIG. 5) constituting a pixel PX (see FIG. 4).

The display element layer 150 may be positioned on the thin film transistor layer 130. The display element layer 150 may be positioned to overlap the display area DA. The display element layer 150 may include a plurality of light emitting elements ED (see FIG. 5). For example, the light emitting element according to an embodiment may include at least one selected from an organic light emitting diode (LED) including an organic light emitting layer, a quantum dot LED including a quantum dot light emitting layer, an inorganic LED including an inorganic semiconductor, and a micro LED, but is not limited thereto.

The thin film encapsulating layer 170 may be positioned on the display element layer 150. The thin film encapsulating layer 170 may be positioned to overlap the display area DA and the non-display area NDA. The thin film encapsulating layer 170 may cover an upper surface and side surfaces of the display element layer 150, and may protect the display element layer 150 from external oxygen and moisture.

The touch sensor layer 180 may be positioned on the thin film encapsulating layer 170. The touch sensor layer 180 may be positioned to overlap the display area DA and the non-display area NDA. The touch sensor layer 180 may sense a user's touch in a mutual capacitance manner or a self-capacitance manner. The touch sensor layer 180 may be omitted according to embodiments.

The color filter layer 190 may be positioned on the touch sensor layer 180. The color filter layer 190 may be positioned to overlap the display area DA and the non-display area NDA. The color filter layer 190 may absorb some of light introduced from the outside of the display device 10 to reduce reflected light by external light. Accordingly, the color filter layer 190 may prevent distortion of colors due to external light reflection.

Since the color filter layer 190 is directly disposed on the touch sensor layer 180, the display device 10 may not include a separate substrate for the color filter layer 190. Accordingly, a thickness of the display device 10 may be relatively small. In addition, the color filter layer 190 may also be omitted according to embodiments.

As illustrated in FIG. 3, a portion of the display layer DPL overlapping the sub-area SBA may be bent. In a state where a portion of the display layer DPL is bent, the display driver 200, the circuit board 300, and the touch driver 400 may overlap the main area MA in the third direction (Z-axis direction).

FIG. 4 is a plan view illustrating an arrangement of a plurality of emission areas in a display area of FIG. 3.

Referring to FIG. 4, the display device 10 according to an embodiment may include a plurality of pixels PX in a portion overlapping the display area DA. Each pixel PX may include a pixel transistor. Each pixel PX may emit light, and may include an emission area EA.

The emission area EA may include first emission areas EA1, second emission areas EA2, and third emission areas EA3 that emit light of different colors. In an embodiment, the first emission area EA1 may emit red light, which is light of a first color, the second emission area EA2 may emit green light, which is light of a second color, and the third emission area EA3 may emit blue light, which is light of a third color, but the present disclosure is not limited thereto.

In some embodiments, at least one first emission area EA1, at least one second emission area EA2, and at least one third emission area EA3 disposed adjacent to each other may constitute one pixel group PXG. The pixel group PXG may be a minimum unit emitting white light. However, types and/or the number of emission areas EA constituting the pixel group PXG may be variously changed according to embodiments.

In an embodiment, as illustrated in FIG. 4, sizes or shapes of the first to third emission areas EA1, EA2, and EA3 may be the same as each other, but the present disclosure is not limited thereto. That is, sizes and shapes of the first to third emission areas EA1, EA2, and EA3 may be variously adjusted according to desired characteristics.

A non-emission area NLA according to an embodiment may be positioned to surround each of the first to third emission areas EA1, EA2, and EA3. The non-emission area NLA may assist in preventing light emitted from each of the first to third emission areas EA1, EA2, and EA3 from being mixed with each other.

In a plan view, a pixel defining layer 151 may be positioned in a portion overlapping the non-emission area NLA. The pixel defining layer 151 may define an opening OP, and may be positioned to surround the opening OP. In a plan view, the opening OP may be positioned in a portion overlapping the emission area EA.

FIG. 5 is a schematic cross-sectional view of a display layer taken along line X1-X1′ of FIG. 4.

FIG. 5 is a cross-sectional view of the display layer DPL of the display device 10, and illustrates cross sections of the substrate 110, the thin film transistor layer 130, the display element layer 150, and the thin film encapsulating layer 170. The substrate 110 in FIG. 5 is substantially the same as that described above with reference to FIG. 3, and any repetitive detailed description thereof will be omitted.

Referring to FIG. 5, the thin film transistor layer 130 may be positioned (or disposed) on the substrate 110. The thin film transistor layer 130 may include a first buffer layer 111, a thin film transistors TFT, a gate insulating layer 113, a first interlayer insulating layer 121, capacitor electrodes CPE, a second interlayer insulating layer 123, first connection electrodes CNE1, a first via layer 125, second connection electrodes CNE2, and a second via layer 127.

The first buffer layer 111 may be positioned on the substrate 110. The first buffer layer 111 may include an inorganic film capable of preventing permeation of air or moisture. In an embodiment, for example, the first buffer layer 111 may include a plurality of inorganic films that are alternately stacked.

The thin film transistor TFT may be disposed on the first buffer layer 111, and may constitute a pixel circuit connected to each of a plurality of pixels. In an embodiment, for example, the thin film transistor TFT may be a driving transistor or a switching transistor of the pixel circuit. The thin film transistor TFT may include an active layer ACT, a source electrode SE, a drain electrode DE, and a gate electrode GE.

The active layer ACT may be positioned on the first buffer layer 111. The active layer ACT may overlap the gate electrode GE in the third direction (Z-axis direction), and may be insulated from the gate electrode GE by the gate insulating layer 113. The source electrode SE and the drain electrode DE may be formed by making a material of the active layer ACT in portions of the active layer ACT conductors.

The gate electrode GE may be positioned on the gate insulating layer 113. The gate electrode GE may overlap the active layer ACT with the gate insulating layer 113 interposed therebetween.

The gate insulating layer 113 may be positioned on the active layer ACT. The gate insulating layer 113 may cover the active layer ACT and the first buffer layer 111, and may insulate the active layer ACT and the gate electrode GE from each other. The gate insulating layer 113 may be provided with contact holes through which the first connection electrodes CNE1 penetrate or extend.

The first interlayer insulating layer 121 may cover the gate electrode GE and the gate insulating layer 113. The first interlayer insulating layer 121 may be provided with contact holes through which the first connection electrodes CNE1 penetrate or extend. The contact holes of the first interlayer insulating layer 121 may be connected to the contact holes of the gate insulating layer 113 and contact holes of the second interlayer insulating layer 123.

The capacitor electrodes CPE may be positioned on the first interlayer insulating layer 121. The capacitor electrode CPE may overlap the gate electrode GE in the third direction (Z-axis direction). The capacitor electrode CPE and the gate electrode GE may form capacitance.

The second interlayer insulating layer 123 may cover the capacitor electrodes CPE and the first interlayer insulating layer 121. The second interlayer insulating layer 123 may be provided with contact holes through which the first connection electrodes CNE1 penetrate. The contact holes of the second interlayer insulating layer 123 may be connected to the contact holes of the first interlayer insulating layer 121 and the contact holes of the gate insulating layer 113.

The first connection electrodes CNE1 may be positioned on the second interlayer insulating layer 123. The first connection electrode CNE1 may electrically connect the drain electrode DE of the thin film transistor TFT and the second connection electrode CNE2 to each other. The first connection electrode CNE1 may be inserted into the contact holes formed in the first interlayer insulating layer 121, the second interlayer insulating layer 123, and the gate insulating layer 113 to be in contact with the drain electrode DE of the thin film transistor TFT.

The first via layer 125 may cover the first connection electrodes CNE1 and the second interlayer insulating layer 123. The first via layer 125 may planarize (or provide a flat surface on) an underlying structure. The first via layer 125 may be provided with contact holes through which the second connection electrodes CNE2 penetrate.

The second connection electrodes CNE2 may be positioned on the first via layer 125. The second connection electrodes CNE2 may be inserted into the contact holes formed in the first via layer 125 to be in contact with the first connection electrodes CNE1. In addition, the second connection electrodes CNE2 may be in electrical contact with first to third anode electrodes AE1, AE2, and AE3. Accordingly, the second connection electrodes CNE2 may electrically connect the thin film transistors TFT and the first to third anode electrodes AE1, AE2, and AE3 to each other.

The second via layer 127 may cover the second connection electrodes CNE2 and the first via layer 125. The second via layer 127 may be provided with contact holes through which the first to third anode electrodes AE1, AE2, and AE3 penetrate.

The display element layer 150 may be positioned on the second via layer 127. The display element layer 150 may include a pixel defining layer 151 and a light emitting element ED.

The pixel defining layer 151 according to an embodiment may be disposed on the second via layer 127 in a portion overlapping the non-emission area NLA. The pixel defining layer 151 may cover edges of the first to third anode electrodes AE1, AE2, and AE3, and may be positioned to surround the first to third anode electrodes AE1, AE2, and AE3.

In cross section, the pixel defining layer 151 may define openings OP, and may be positioned to surround the openings OP. The pixel defining layer 151 may expose the first to third anode electrodes AE1, AE2, and AE3 in portions overlapping the openings OP.

The pixel defining layer 151 may allow the first to third anode electrodes AE1, AE2, and AE3 from being spaced apart and insulated from each other.

The pixel defining layer 151 may include an inorganic insulating material. In an embodiment, for example, the pixel defining layer 151 may include at least one selected from aluminum oxide, titanium oxide, tantalum oxide, hafnium oxide, zinc oxide, silicon oxide, silicon nitride, and silicon oxynitride.

The light emitting element ED according to an embodiment may include a first light emitting element ED1 disposed in the first emission area EA1, a second light emitting element ED2 disposed in the second emission area EA2, and a third light emitting element ED3 disposed in the third emission area EA3. The first light emitting element ED1, the second light emitting element ED2, and the third light emitting element ED3 may be spaced apart from each other.

The first light emitting element ED1, the second light emitting element ED2, and the third light emitting element ED3 may emit light of different colors. In an embodiment, for example, the first light emitting element ED1 may emit red light, which is light of a first color, the second light emitting element ED2 may emit green light, which is light of a second color, and the third light emitting element ED3 may emit blue light, which is light of a third color.

In an embodiment, the first light emitting element ED1 may include a first anode electrode AE1, a first light emitting layer EL1, and a cathode electrode CE, the second light emitting element ED2 may include a second anode electrode AE2, a second light emitting layer EL2, and a cathode electrode CE, and the third light emitting element ED3 may include a third anode electrode AE3, a third light emitting layer EL3, and a cathode electrode CE. The first light emitting element ED1, the second light emitting element ED2, and the third light emitting element ED3 may emit light of different colors depending on types of a first organic light emitting layer EML1, a second organic light emitting layer EML2, and a third organic light emitting layer EML3 that are respectively included in the first light emitting layer EL1, the second light emitting layer EL2, and the third light emitting layer EL3. Detailed contents will be described later.

The first to third anode electrodes AE1, AE2, and AE3 according to an embodiment may be positioned on the second via layer 127. The first to third pixel electrodes AE1, AE2, and AE3 may be electrically connected to the drain electrodes DE of the thin film transistors TFT through the first connection electrodes CNE1 and the second connection electrodes CNE2.

The first to third anode electrodes AE1, AE2, and AE3 may be positioned to be spaced apart from each other on the second via layer 127, and may be insulated from each other by the pixel defining layer 151. In an embodiment, the first anode electrode AE1 may be positioned in a portion overlapping the first emission area EA1, the second anode electrode AE2 may be positioned in a portion overlapping the second emission area EA2, and the third anode electrode AE3 may be positioned in a portion overlapping the third emission area EA3.

Each of the first to third anode electrodes AE1, AE2, and AE3 may have a stacked film structure in which a layer made of a material having a high work function, such indium tin oxide (ITO), indium zinc oxide (IZO), zinc oxide (ZnO), or indium oxide (In₂O₃) and a layer made of a reflective material such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), or mixtures thereof are stacked. In an embodiment, for example, each of the first to third anode electrodes AE1, AE2, and AE3 may have a multilayer structure of ITO/Mg, ITO/MgF₂, ITO/Ag, or ITO/Ag/ITO, but is not limited thereto.

The first to third light emitting layers EL1, EL2, and EL3 according to an embodiment may be positioned on the first to third anode electrodes AE1, AE2, and AE3, respectively. The first to third light emitting layers EL1, EL2, and EL3 may be spaced apart from each other. in an embodiment, the first light emitting layer EL1 may be positioned in a portion overlapping the first emission area EA1, the second light emitting layer EL2 may be positioned in a portion overlapping the second emission area EA2, and the third light emitting layer EL3 may be positioned in a portion overlapping the third emission area EA3.

In an embodiment, the first light emitting layer EL1 may include a hole injection layer HIL, a hole transporting layer HTL, a first organic light emitting layer EML1, and an electron layer EITL, the second light emitting layer EL2 may include a hole injection layer HIL, a hole transporting layer HTL, a second organic light emitting layer EML2, and an electron layer EITL, and the third light emitting layer EL3 may include a hole injection layer HIL, a hole transporting layer HTL, a third organic light emitting layer EML3, and an electron layer EITL.

The first light emitting layer EL1, the second light emitting layer EL2, and the third light emitting layer EL3 may emit light of different colors depending on materials included in the first organic light emitting layer EML1, the second organic light emitting layer EML2, and the third organic light emitting layer EML3. In an embodiment, for example, the first light emitting layer EL1 may emit the red light, which is the light of the first color, the second light emitting layer EL2 may emit the green light, which is the light of the second color, and the third light emitting layer EL3 may emit the blue light, which is the light of the third color, but the present disclosure is not limited thereto.

In an embodiment, the respective hole injection layers HIL and hole transporting layers HTL included in the first to third light emitting layers EL1, EL2, and EL3 may include a same material as each other. In such an embodiment, the hole injection layers HIL and the hole transporting layers HTL included in the first to third light emitting layers EL1, EL2, and EL3 may be common layers. However, the hole injection layers HIL and the hole transporting layers HTL included in the first to third light emitting layers EL1, EL2, and EL3 may be spaced apart from each other with the pixel defining layer 151 in portions overlapping the first to third emission areas EA1, EA2, and EA3.

In an embodiment, the hole injection layer HIL may effectively inject holes and quickly perform the movement of the holes. The hole injection layer HIL may have a single layer made of a single material, a single layer made of a plurality of different materials, or a multilayer structure including a plurality of layers respectively made of different materials.

The hole injection layer HIL according to an embodiment may be subjected to a photo pattern process including a dry etching process and a vacuum heat treatment process performed at about 150° C. or higher in a fabricating process of the display device 10. Accordingly, the hole injection layer HIL may be desired to have etching resistance characteristics and heat resistance characteristics in addition to hole injection characteristics. The fabricating process will be described later.

The hole injection layer HIL may include a conductive high-molecular material. In an embodiment, for example, the hole injection layer HIL may include at least one selected from poly(3,4-ethylenedioxythiophene): poly(styrenesulfonate)(AI4083) (available from CLEVIOS-Heraeus GmbH), tris(4-carbazoyl-9-ylphenyl)amine (TCTA), 4,4′-bis(N-carbazolyl)-1,1′-biphenyl (CBP), 2,2′,2″(1,3,5-benzinetriyl)-tris(1-phenyl-1-H-benzimidazole) (TPBI), and bis[2-(2-pyridinyl-N)phenyl-C](acetylacetonato) iridium(III) (Ir(ppy)₂(acac).

In addition, the hole injection layer HIL may include further include at least one selected from poly(3-hexylthiophene) (P3HT), N,N′-di(1-naphthyl)-N, N′-diphenyl-(1,1′-biphenyl)-4,4′-diamine (NPB), tris(8-hydroxyquinolinato)aluminum (Alq₃), 1,3-bis(9-carbazolyl)benzene (mCP), 4,4′-cyclohexylidenebis[N,N-bis(4-methylphenyl)aniline] (TAPC), fac-tris(2-phenylpyridine) iridium (Ir(ppy)₃), 2,9-dimethyl-4,7-diphenyl-1,10-phenanthroline (BCP), and Spiro-OMeTAD (2,2′,7,7′-tetrakis(N, N-di-p-methoxyphenylamine)9,9′-spirobifluorene), but is not limited thereto.

In a case where the hole injection layer HIL uses a low-molecular material other than the materials described above, it may cause a material reliability defect in performing the photo pattern process including the dry etching process and the vacuum heat treatment process. Here, the material reliability defect may include deterioration of material lifespan characteristics, deterioration of light emitting efficiency characteristics, a shadow defect due to light emitting unevenness, and the like.

In an embodiment, the hole transporting layers HTL may have high mobility such that the holes injected from the hole injection layers HIL may efficiently move to the first to third organic light emitting layers EML1, EML2, and EML3. The hole transporting layer HTL may have a single layer made of a single material, a single layer made of a plurality of different materials, or a multilayer structure including a plurality of layers respectively made of different materials.

The hole transporting layer HTL according to an embodiment may be subjected to a photo pattern process including a dry etching process and a vacuum heat treatment process performed at about 150° C. or higher in a fabricating process of the display device 10. The fabricating process will be described later. The hole transporting layer HTL according to an embodiment be required to have etching resistance characteristics and heat resistance characteristics in addition to hole movement characteristics, and may include a conductive high-molecular material. In an embodiment, for example, the hole transporting layer HTL may include at least one selected from poly(3,4-ethylenedioxythiophene): poly(styrenesulfonate)(AI4083) (available from CLEVIOS-Heraeus GmbH), tris(4-carbazoyl-9-ylphenyl)amine (TCTA), 4,4′-bis(N-carbazolyl)-1,1′-biphenyl (CBP), 2,2′,2″(1,3,5-benzinetriyl)-tris(1-phenyl-1-H-benzimidazole) (TPBI), and bis[2-(2-pyridinyl-N)phenyl-C](acetylacetonato) iridium(III) (Ir(ppy)₂(acac).

In addition, the hole transporting layer HTL may include further include at least one selected from poly(3-hexylthiophene) (P3HT), N, N′-di(1-naphthyl)-N, N′-diphenyl-(1,1′-biphenyl)-4,4′-diamine (NPB), tris(8-hydroxyquinolinato)aluminum (Alq₃), 1,3-bis(9-carbazolyl)benzene (mCP), 4,4′-cyclohexylidenebis[N, N-bis(4-methylphenyl)aniline] (TAPC), fac-tris(2-phenylpyridine) iridium (Ir(ppy)₃), 2,9-dimethyl-4,7-diphenyl-1,10-phenanthroline (BCP), and Spiro-OMeTAD (2,2′,7,7′-tetrakis(N, N-di-p-methoxyphenylamine)9,9′-spirobifluorene), but is not limited thereto.

In a case where the hole transporting layer HTL uses a low-molecular material other than the materials described above, it may cause a material reliability defect in performing the photo pattern process including the dry etching process and the vacuum heat treatment process. Here, the material reliability defect may include deterioration of material lifespan characteristics, deterioration of light emitting efficiency characteristics, a shadow defect due to light emitting unevenness, and the like.

According to an embodiment, the hole injection layer HIL and the hole transporting layer HTL may be merged with each other as one layer. In an embodiment, for example, where the hole injection layer HIL and the hole transporting layer HTL are merged with each other as one layer, the hole injection layer HIL and the hole transporting layer HTL may be expressed as a hole layer.

Each of the first to third organic light emitting layers EML1, EML2, and EML3 according to an embodiment may include a host material and a dopant material. The host material is not particularly limited as long as it is a commonly used material, but may include, for example, at least one selected from tris(8-hydroxyquinolinato)aluminum (Alq₃), 4,4′-bis(N-carbazolyl)-1,1′-biphenyl (CBP), poly(n-vinylcabazole) (PVK), 9,10-di(naphthalene-2-yl)anthracene (ADN), 4,4′,4″tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2″ dimethyl-biphenyl (CDBP), 2-methyl-9,10-bis(naphthalen-2-yl)anthracene (MADN), or the like.

The first to third organic light emitting layers EML1, EML2, and EML3 may emit light of different colors depending on materials included therein.

In an embodiment, for example, where the first organic light emitting layer EML1 emits the red light, the first organic light emitting layer EML1 may include a fluorescent material including perylene or tris(dibenzoylmethanato)phenanthoroline europium (PBD: Eu(DBM)3(phen)). In such an embodiment, the dopant material included in the first organic light emitting layer EML1 is not particularly limited as long as it is a commonly used material, but may include, for example, at least one selected from a metal complex or an organometallic complex such as bis(1-phenylquinoline)acetylacetonate iridium (PIQIr(acac)), bis(1-phenylquinoline)acetylacetonateiridium (PQIr(acac)), tris(1-phenylquinoline)iridium (PQIr), and octaethylporphyrin platinum (PtOEP).

In an embodiment, for example, where the second organic light emitting layer EML2 emits the green light, the second organic light emitting layer EML2 may include a fluorescent material including tris(8-hydroxyquinolinato)aluminum (Alq₃). In such an embodiment, the dopant material included in the second organic light emitting layer EML2 is not particularly limited as long as it is a commonly used material, but may include, for example, at least one selected from a metal complex or an organometallic complex such as fac-tris(2-phenylpyridine)iridium (Ir(ppy)₃).

In an embodiment, for example, where the third organic light emitting layer EML3 emits the blue light, the third organic light emitting layer EML3 may include a fluorescent material including at least one selected from spiro-DPVBi, spiro-6P, distyryl-benzene (DSB), distyryl-arylene (DSA), a polyfluorene (PFO)-based polymer, and a poly(p-phenylene vinylene) (PPV)-based polymer. In such an embodiment, the dopant material included in the third organic light emitting layer EML3 is not particularly limited as long as it is a commonly used material, but may include, for example, at least one selected from a metal complex or an organometallic complex such as (4,6-F2ppy)₂Irpic.

However, the materials included in the first to third organic light emitting layers EML1, EML2, and EML3 are not limited to the examples described above.

The electronic layer EITL according to an embodiment may be disposed on the first to third organic light emitting layers EML1, EML2, and EML3. The electron layer EITL may be a common layer positioned in portions overlapping the first to third emission areas EA1, EA2, and EA3 and the non-emission area NLA. The electron layer EITL may extend without being spaced apart from each other in the first to third emission areas EA1, EA2, and EA3 and be formed integrally.

The electron layer EITL may serve to inject and transport electrons transferred from the cathode electrode CE into the first to third organic light emitting layers EML1, EML2, and EML3.

In an embodiment, the electron layer EITL may include a low-molecular material. In an embodiment, for example, the electron layer EITL may include at least one selected from tris(8-hydroxyquinolinato)aluminum (Alq₃), 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), and mixtures thereof, lanthanide metals such as LiF, lithium quinolate (LiQ), Li₂O, BaO, NaCl, CsF, and Yb, halogenated metals such as RbCl and RbI, or the like, but is not limited thereto.

According to an embodiment, the electron layer EITL may also be formed to be separated into an electron transporting layer and an electron injection layer that are sequentially stacked in the third direction (Z-axis direction).

The cathode electrode CE according to an embodiment may be disposed on the first to third light emitting layers EL1, EL2, and EL3. The cathode electrode CE according to an embodiment may be a common electrode positioned in portions overlapping the first to third emission areas EA1, EA2, and EA3 and the non-emission area NLA. The cathode layer CE may extend without being spaced apart from each other in the first to third emission areas EA1, EA2, and EA3 and be formed integrally.

The cathode electrode CE may receive a common voltage or a low potential voltage. In an embodiment, when the first to third anode electrodes AE1, AE2, and AE3 receive a voltage corresponding to a data voltage and the cathode electrode CE receives the low potential voltage, holes and electrons may move to the first to third organic light emitting layers EML1, EML2, and EML3 through the hole transporting layer HTL and the hole injection layer HIL, and the electron layer EITL, respectively, and may combine with each other in the first to third organic light emitting layers EML1, EML2, and EML3 to emit light. That is, potential differences are formed between the first to third anode electrodes AE1, AE2, and AE3 and the cathode electrode CE, such that the first to third light emitting layers EL1, EL2, and EL3 may emit the light.

The cathode electrode CE may include a metal having high electrical conductivity. In an embodiment, for example, the cathode electrode CE may include a layer made of a material having a small work function, such as Li, Ca, LiF/Ca, LiF/Al, Al, Mg, Ag, Pt, Pd, Ni, Au, Nd, Ir, Cr, BaF, Ba, or compounds or mixtures thereof (e.g., a mixture of Ag and Mg, etc.).

The thin film encapsulating layer 170 may be positioned on the display element layer 150. The thin film encapsulating layer 170 may be disposed in portions overlapping the first to third emission areas EA1, EA2, and EA3 and the non-emission area NLA. The thin film encapsulating layer 170 may include a first encapsulating layer 171, a second encapsulating layer 173, and a third encapsulating layer 175 that are sequentially stacked.

The first encapsulating layer 171 may be positioned on the cathode electrode CE. The first encapsulating layer 171 may effectively prevent oxygen or moisture from permeating into the light emitting element ED.

The first encapsulating layer 171 may include one or more inorganic insulating materials. In an embodiment, for example, the first encapsulating layer 171 may include at least one selected from aluminum oxide, titanium oxide, tantalum oxide, hafnium oxide, zinc oxide, silicon oxide, silicon nitride, and silicon oxynitride.

The second encapsulating layer 173 may be positioned on the first encapsulating layer 171. The second encapsulating layer 173 may protect the display element layer 150 from foreign substances.

The second encapsulating layer 173 may include a polymer-based material. In an embodiment, for example, the second encapsulating layer 173 may include at least one selected from a silicone-based resin, an acrylic resin, an epoxy-based resin, and mixtures thereof.

The third encapsulating layer 175 may be positioned on the second encapsulating layer 173. The third encapsulating layer 175 may effectively prevent oxygen or moisture from permeating into the display element layer 150 and the first encapsulating layer 171.

The third encapsulating layer 175 may include a same material as the first encapsulating layer 171, and repetitive detailed description thereof will be omitted.

The first encapsulating layer 171 according to an embodiment may be formed at the same thickness along a profile formed by the display element layer 150 disposed therebelow. Accordingly, the first encapsulating layer 171 may have a step or include a portion having stepped structure. The step included in the first encapsulating layer 171 may be planarized by the second encapsulating layer 173. Accordingly, the third encapsulating layer 175 according to an embodiment may be formed without a step.

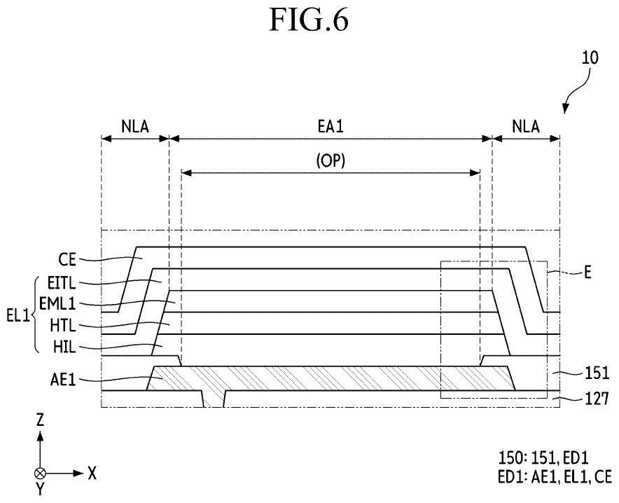

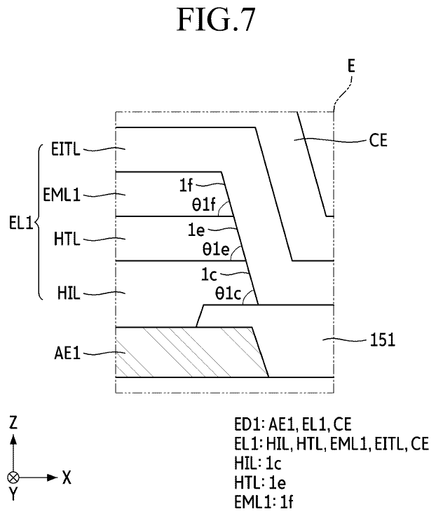

FIG. 6 is an enlarged cross-sectional view of a display element layer overlapping a first emission area in FIG. 5, and FIG. 7 is an enlarged cross-sectional view of area ‘E’ in FIG. 6.

Referring to FIGS. 6 and 7, the display element layer 150 according to an embodiment may include a pixel defining layer 151 and a first light emitting element ED1 in a portion overlapping the first emission area EA1. The first light emitting element ED1 may include a first anode electrode AE1, a first light emitting layer EL1, and a cathode electrode CE in a portion overlapping the first emission area EA1.

The pixel defining layer 151 according to an embodiment may define an opening OP in a portion overlapping the first emission area EA1, and the first anode electrode AE1 may be exposed in a portion overlapping the opening OP. The pixel defining layer 151 may be positioned in a portion overlapping the first emission area EA1 and the non-emission area NLA.

The first light emitting layer EL1 according to an embodiment may be positioned on the first anode electrode AE1, and may include a hole injection layer HIL, a hole transporting layer HTL, a first organic light emitting layer EML1, and an electron layer EITL.

The hole injection layer HIL according to an embodiment may be positioned on the first anode electrode AE1 and the pixel defining layer 151. The hole injection layer HIL may be in contact with the first anode electrode AE1 in a portion overlapping the opening OP.

In the fabricating process of the display device 10, the hole injection layer HIL may be entirely formed on the first anode electrode AE1 and the pixel defining layer 151 and be then formed in a shape illustrated in FIGS. 6 and 7 by the photo pattern process including the dry etching process. In other words, the hole injection layer HIL according to an embodiment may be formed without using a separate mask in the fabricating process.

Accordingly, the hole injection layer HIL may include a side surface 1c facing the non-emission area NLA, and the side surface 1c of the hole injection layer HIL may be an inclined surface. In an embodiment, for example, the side surface 1c of the hole injection layer HIL may be inclined between the first direction (X-axis direction) and the third direction (Z-axis direction), and may have a clear cross section without a tail defect caused by the use of the mask.

The side surface 1c of the hole injection layer HIL may have a high taper angle. In an embodiment, for example, an inclination angle θ1c formed by the side surface 1c of the hole injection layer HIL and an upper surface of the pixel defining layer 151 may be in a range of about 60° to about 90° (i.e., greater than or equal to about 60° and less than or equal to about 90°).

In an embodiment, clear cross section and high taper angle characteristics of the side surface 1c of the hole injection layer HIL may mean that the hole injection layer HIL is formed by the photo pattern process including the dry etching process in the fabricating process of the display device 10.

The hole transporting layer HTL according to an embodiment may be positioned on the hole injection layer HIL to be in contact with the hole injection layer HIL.

In the fabricating process of the display device 10, the hole transporting layer HTL may be entirely formed on the hole injection layer HIL in a portion overlapping the first anode electrode AE1 and the pixel defining layer 151 and be then formed in a shape illustrated in FIGS. 6 and 7 by the photo pattern process including the dry etching process. In other words, the hole transporting layer HTL according to an embodiment may be formed without using a separate mask in the fabricating process.

Accordingly, the hole transporting layer HTL may include a side surface 1e facing the non-emission area NLA, and the side surface 1e of the hole transporting layer HTL may be an inclined surface. In an embodiment, the side surface 1e of the hole transporting layer HTL may be inclined between the first direction (X-axis direction) and the third direction (Z-axis direction), and may have a clear cross section without a tail defect caused by the use of the mask.

The side surface 1e of the hole transporting layer HTL may have a high taper angle. In an embodiment, for example, an inclination angle θ1e formed by the side surface 1e of the hole transporting layer HTL and the hole injection layer HIL may be in a range of about 60° to about 90°.

In an embodiment, clear cross section and high taper angle characteristics of the side surface 1e of the hole transporting layer HTL may mean that the hole transporting layer HTL is formed by the photo pattern process including the dry etching process in the fabricating process of the display device 10.

In an embodiment, the hole injection layer HIL and the hole transporting layer HTL may be formed through a same etching process in the fabricating process of the display device 10. Accordingly, the side surface 1c of the hole injection layer HIL and the side surface 1e of the hole transporting layer HTL may be positioned on a same line or a same plane, but are not limited thereto.

In another embodiment, when the hole injection layer HIL and the hole transporting layer HTL are merged with each other to be formed as the hole layer, the hole layer may have the same structural characteristics as the hole injection layer HIL.

The first organic light emitting layer EML1 according to an embodiment may be positioned on the hole transporting layer HTL to be in contact with the hole transporting layer HTL.

In the fabricating process of the display device 10, the first organic light emitting layer EML1 may be entirely formed on the hole transporting layer HTL in a portion overlapping the first anode electrode AE1 and the pixel defining layer 151 and be then formed in a shape illustrated in FIGS. 6 and 7 by the photo pattern process including the dry etching process. In other words, the first organic light emitting layer EML1 according to an embodiment may be formed without using a separate mask in the fabricating process.

Accordingly, the first organic light emitting layer EML1 may include a side surface 1f facing the non-emission area NLA, and the side surface 1f of the first organic light emitting layer EML1 may be an inclined surface. In an embodiment, the side surface 1f of the first organic light emitting layer EML1 may be inclined between the first direction (X-axis direction) and the third direction (Z-axis direction), and may have a clear cross section without a tail defect caused by the use of the mask.

The side surface 1f of the first organic light emitting layer EML1 may have a high taper angle. In an embodiment, for example, an inclination angle θ1f formed by the side surface 1f of the first organic light emitting layer EML1 and the hole transporting layer HTL may be in a range of about 60° to about 90°.

In an embodiment, clear cross section and high taper angle characteristics of the side surface 1f of the first organic light emitting layer EML1 may mean that the first organic light emitting layer EML1 is formed by the photo pattern process including the dry etching process in the fabricating process of the display device 10.

The hole injection layer HIL, the hole transporting layer HTL and the first organic light emitting layer EML1 according to an embodiment may be simultaneously formed through the same etching process in the fabricating process. Accordingly, the side surface 1c of the hole injection layer HIL, the side surface 1e of the hole transporting layer HTL, and the side surface 1f of the first organic light emitting layer EML1 may be positioned on a same line or on a same plane, but are not limited thereto.

In an embodiment, the electron layer EITL may be positioned on the first organic light emitting layer EML1. The electron layer EITL may completely cover the hole injection layer HIL, the hole transporting layer HTL, and the first organic emitting layer EML1. Accordingly, the electron layer EITL may include a high step in a portion overlapping the hole injection layer HIL, the hole transporting layer HTL, and the first organic emitting layer EML1.

In an embodiment, the electron layer EITL may be in contact with the side surface 1c of the hole injection layer HIL, the side surface 1e of the hole transporting layer HTL, and the side surface 1f of the first organic emitting layer EML1.

In an embodiment, the cathode electrode CE may be positioned on the first emitting layer EL1. As described above, the cathode electrode CE may be a common layer positioned in a portion overlapping the first emission area EA1 and the non-emission area NLA.

The cathode electrode CE may be in contact with the electron layer EITL, and may completely cover the electron layer EITL. In addition, the cathode electrode CE may completely cover the hole injection layer HIL, the hole transporting layer HTL, and the first organic light emitting layer EML1. Accordingly, the cathode electrode CE may include a high step in a portion overlapping the hole injection layer HIL, the hole transporting layer HTL, and the first organic emitting layer EML1.

For convenience of illustration and description, the display element layer 150 positioned in a portion overlapping the first emission area EA1 has been illustrated in an enlarged form, but the display element layer 150 positioned in portions overlapping the second emission area EA2 and the third emission area EA3 may have a same structural characteristics as the display element layer 150 positioned in the portion overlapping the first emission area EA1.

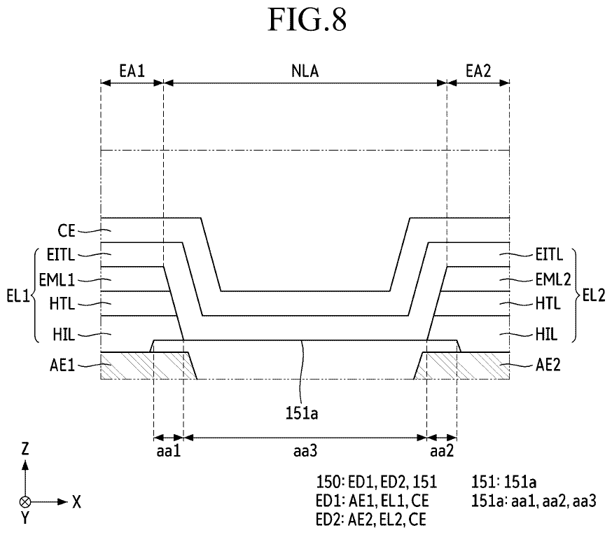

FIG. 8 is a schematic enlarged cross-sectional view of the display element layer overlapping a non-emission area positioned between the first emission area and a second emission area in FIG. 5.

Referring to FIG. 8 in addition to FIGS. 1 to 7, the display element layer 150 according to an embodiment may include a first emission element ED1 in a portion overlapping the first emission area EA1, a second emission element ED2 in a portion overlapping the second emission area EA2, and a pixel defining layer 151 in a portion overlapping the non-emission area NLA.

In an embodiment, the first emission element ED1 and the second emission element ED2 may be spaced apart from each other in the first direction (X-axis direction) with the pixel defining layer 151 interposed therebetween. In such an embodiment, the hole injection layer HIL, the hole transporting layer HTL, and the first organic light emitting layer EML1 included in the first light emitting layer EL1 of the first light emitting element ED1 may be spaced apart from the hole injection layer HIL, the hole transporting layer HTL, and the second organic light emitting layer EML2 included in the second light emitting layer EL2 of the second light emitting element ED2.

In some embodiments, the pixel defining layer 151 may include a first surface 151a facing one side in the third direction (Z-axis direction). The first surface 151a of the pixel defining layer 151 may include a first portion aa1, a second portion aa2, and a third portion aa3 corresponding to overlapping structures thereof. In such an embodiment, the first portion aa1 may overlap the first light emitting element ED1, and may be in contact with the hole injection layer HIL of the first light emitting element ED1. In addition, the second portion aa2 may overlap the second light emitting element ED2, and may be in contact with the hole injection layer HIL of the second light emitting element ED2. In other words, the first portion aa1 may overlap the first organic light emitting layer EML1, and the second portion aa2 may overlap the second organic light emitting layer EML2.

The first portion aa1 and the second portion aa2 may be spaced apart from each other with the third portion aa3 interposed therebetween, and may be connected to each other through the third portion aa3.

The display device 10 according to an embodiment may include a separate structure in the portion overlapping the non-emission area NLA by forming the first to third light emitting layers EL1, EL2, and EL3 by a coating process and the photo pattern process in the fabricating process. In other words, the third portion aa3 included in the first surface 151a of the pixel defining layer 151 may be in entire contact with the electronic layer EITL.

Hereinafter, an embodiment of a method of fabricating the display device 10 of FIG. 5 will be described.

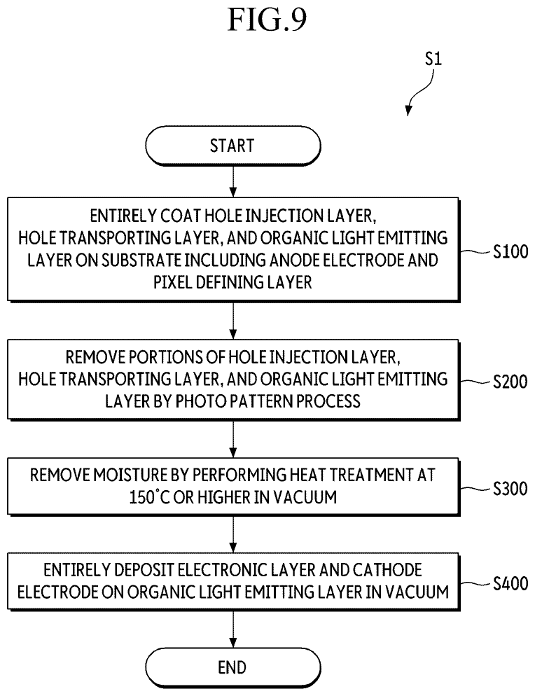

FIG. 9 is a flowchart illustrating a method of fabricating the display element layer according to an embodiment.

Referring to FIG. 9, an embodiment of the method of fabricating the display device 10 according to an embodiment (S1) may include entirely coating a hole injection layer, a hole transporting layer, and an organic light emitting layer on a substrate including an anode electrode and a pixel defining layer (S100), removing portions of the hole injection layer, the hole transporting layer, and the organic light emitting layer by a photo pattern process (S200), removing moisture by performing heat treatment at 150° C. or higher in a vacuum environment (S300), and entirely depositing an electronic layer and a cathode electrode on the organic light emitting layer in a vacuum environment (S400).

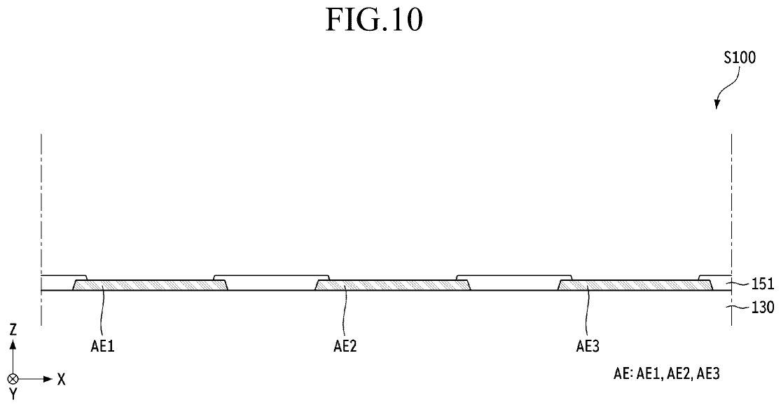

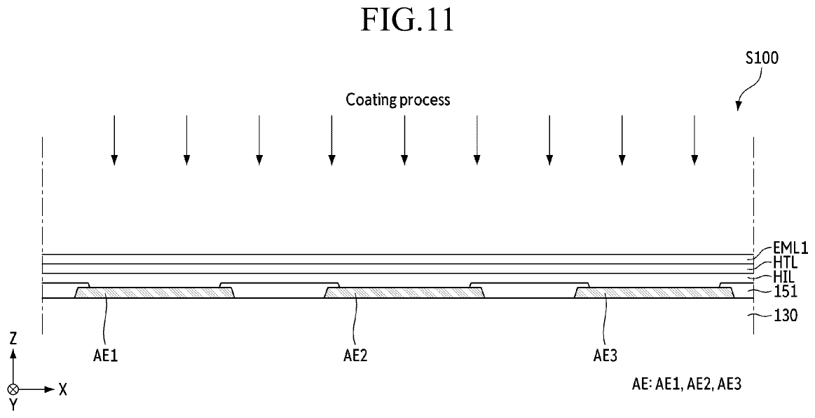

FIGS. 10 and 11 are cross-sectional views illustrating S100 of FIG. 9.

Hereinafter, the entire coating of the hole injection layer, the hole transporting layer, and the organic light emitting layer on the substrate including the anode electrode and the pixel defining layer (S100) will be described.

Referring to FIGS. 10 and 11, an anode electrode AE and a pixel defining layer 151 are formed on the thin film transistor layer 130. The anode electrode AE may include first to third anode electrodes AE1, AE2, and AE3. Although not illustrated in FIGS. 10 and 11, the thin film transistor layer 130 may be disposed on the substrate 110, and a structure of the thin film transistor layer 130 is the same as that described above with reference to FIG. 5.

The pixel defining layer 151 may be disposed between a plurality of first to third anode electrodes AE1, AE2, and AE3. The pixel defining layer 151 may cover edges of the anode electrode AE. The pixel defining layer 151 may allow the first to third anode electrodes AE1, AE2, and AE3 from being spaced apart and insulated from each other.

Subsequently, a hole injection layer HIL, a hole transporting layer HTL, and a first organic light emitting layer EML1 are entirely coated on the anode electrode AE and the pixel defining layer 151. The hole injection layer HIL and the hole transporting layer HTL may include the conductive high-molecular material described above. Any repetitive detailed description of the materials will be omitted.

In this process, the hole injection layer HIL, the hole transporting layer HTL, and the first organic light emitting layer EML1 may be formed by a coating process.

In this process, the coating process refers to a technology of applying an organic material as a thin layer on the substrate. In an embodiment, for example, the coating process may include spin coating, spray coating, dip coating, roll to roll printing, screen printing, or the like.

However, the coating process performed in the present process may not include an inkjet method of forming a film by dropping an organic material between a plurality of dam structures.

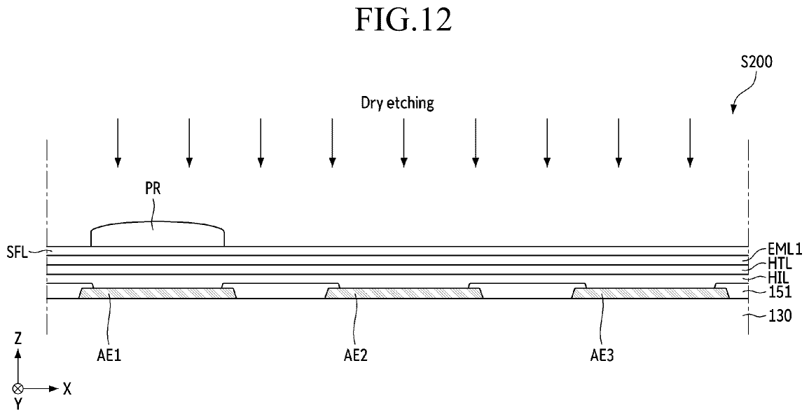

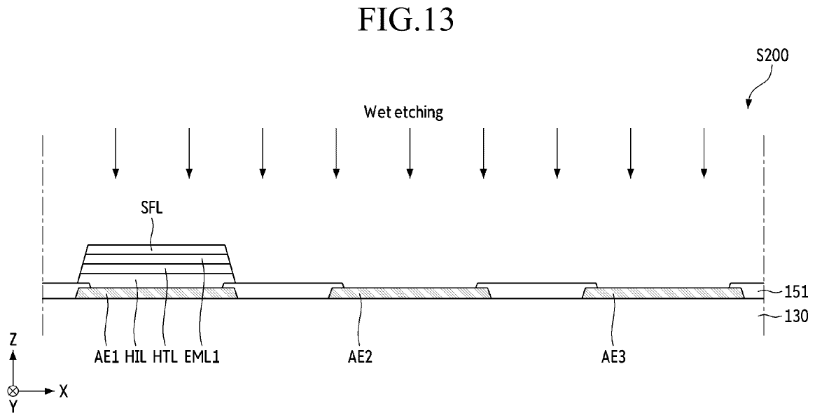

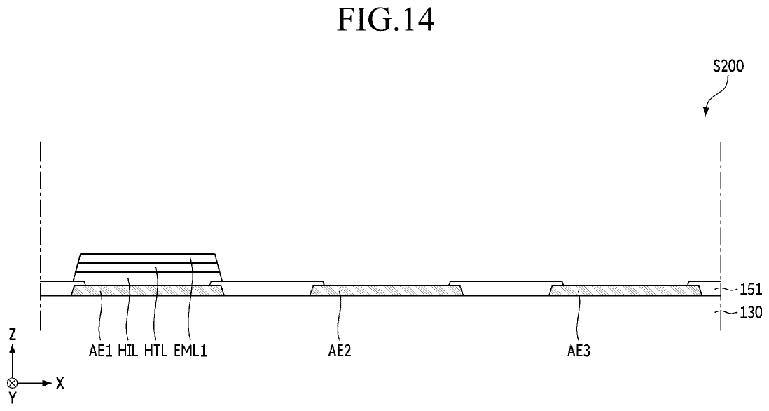

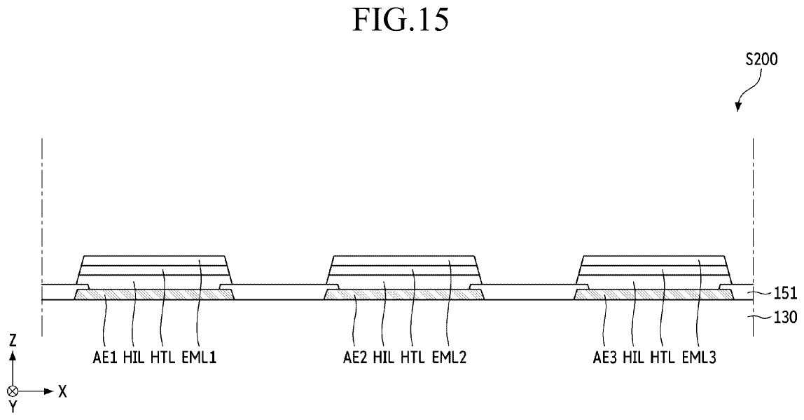

FIGS. 12 to 15 are cross-sectional views illustrating S200 of FIG. 9.

Hereinafter, the removing of the portions of the hole injection layer, the hole transporting layer, and the organic light emitting layer by the photo pattern process (S200) will be described.

Referring to FIGS. 12 to 15, a sacrificial layer SFL is formed on the first organic light emitting layer EML1. The sacrificial layer SFL may protect the first organic light emitting layer EML1 from an etchant when being subjected to a subsequent etching process. The above-described etchant may refer to a liquid and a gas used in an etching solution.

The sacrificial layer SFL may be directly formed on the first organic light emitting layer EML1, and may include a metal material. In an embodiment, for example, the sacrificial layer SFL may include aluminum (Al), but is not limited thereto.

Next, a photoresist PR is formed on the sacrificial layer SFL in a portion overlapping the first anode electrode AE1, and a dry etching process is performed using the photoresist PR as a mask.

In this process, the hole injection layer HIL, the hole transporting layer HTL, and the first organic light emitting layer EML1 that do not overlap the photoresist PR may be removed, and for this reason, the second anode electrode AE2 and the third anode electrode AE3 may be exposed again.

The above-mentioned photoresist PR may be removed through a separate ashing process after the dry etching process.

Subsequently, the sacrificial layer SFL is removed through a wet etching process.

In this process, the wet etching process may use a non-alkaline etching solution to minimize damage to the first organic light emitting layer EML1.

This process may be performed in a chamber of an air atmosphere, and accordingly, the hole injection layer HIL, the hole transporting layer HTL, and the first organic light emitting layer EML1 may be exposed to the air. Consequently, a hole injection layer HIL, a hole transporting layer HTL, and a first organic light emitting layer EML1 positioned on the first anode electrode AE1 may be formed.

Referring to FIGS. 5 to 14 again, the hole injection layer HIL, the hole transporting layer HTL, and the first organic light emitting layer EML1 according to an embodiment may be formed in shapes illustrated in FIGS. 5 to 14 through the dry etching process without a separate fine metal mask, and may thus have clear side surfaces without tail defects and mask shadow defects and have high taper angles. Accordingly, the display device 10 according to an embodiment may have fabrication easiness.

Next, a hole injection layer HIL, a hole transporting layer HTL, and a second organic light emitting layer EML2 overlapping the second anode electrode AE2 are formed by repeating the above-described process, and a hole injection layer HIL, a hole transporting layer HTL, and a third organic light emitting layer EML3 overlapping the third anode electrode AE3 are then formed by repeating the above-described process again.

The present process may be performed under an air atmosphere, and accordingly, the hole injection layer HIL, the hole transporting layer HTL, and the first to third organic light emitting layers EML1, EML2, and EML3 may be exposed to the air and moisture.

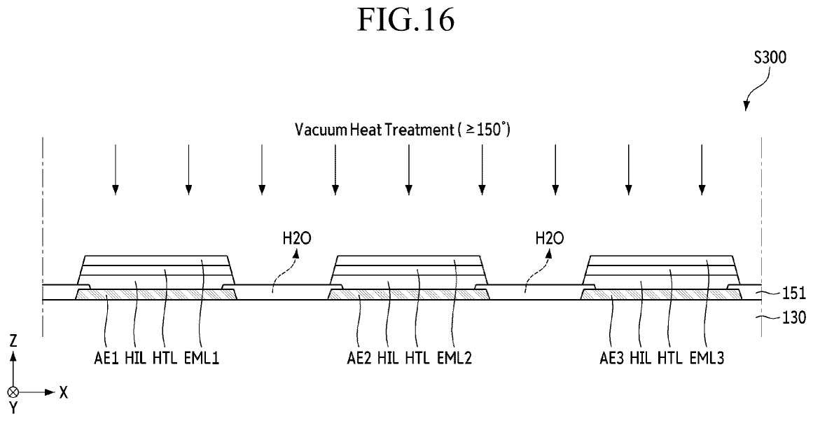

FIG. 16 is a cross-sectional view illustrating S300 of FIG. 9.

Hereinafter, the removing of the moisture by performing the heat treatment at 150° C. or higher in the vacuum environment (S300) will be described.

Referring to FIG. 16 in addition to FIGS. 1 to 15, the display device 10 according to an embodiment may be put into a vacuum chamber of which an internal space is created as a vacuum atmosphere, and a vacuum heat treatment process may be performed. The vacuum heat treatment process may be performed at a temperature of about 150° C. or higher. In this process, most of the moisture (H₂O) included in the display device 10 may be removed.

For example, when the vacuum heat treatment process is performed at a temperature lower than about 150° C., the moisture may remain in the display device 10. When the moisture remains in the display device 10, a reliability defect such as oxidation of the cathode electrode and deterioration of light emitting efficiency may be caused in the display device 10.

The hole injection layer HIL and the hole transporting layer HTL according to an embodiment include a conductive high-molecular material having heat resistance characteristics, and may accordingly have robust characteristics even though the hole injection layer HIL and the hole transporting layer HTL are exposed to a high temperature of about 150° C. or higher.

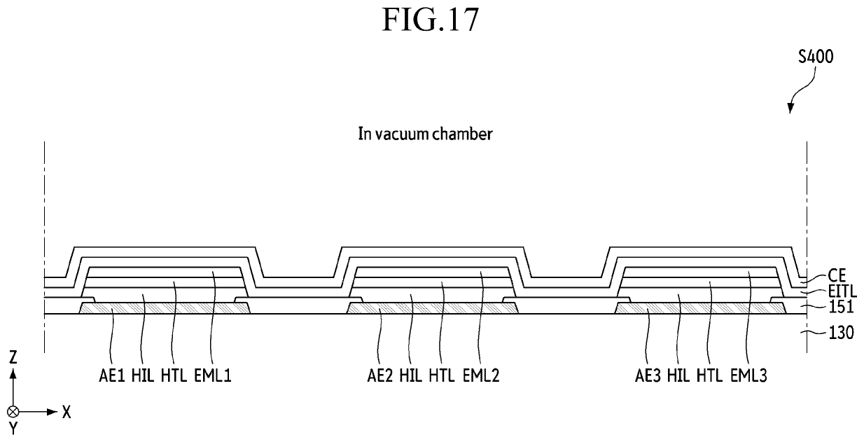

FIG. 17 is a cross-sectional view illustrating S400 of FIG. 9.

Hereinafter, the entire depositing of the electronic layer and the cathode electrode on the organic light emitting layer in the vacuum environment (S400) will be described.

Referring to FIG. 17 in addition to FIGS. 1 to 16, an electron layer EITL and a cathode electrode CE are entirely formed on the first to third organic light emitting layers EML1, EML2, and EML3 from which the moisture (H₂O) is removed. The electron layer EITL and the cathode electrode CE may be formed in a vacuum chamber in which a vacuum atmosphere is created.

In this process, the electron layer EITL may be formed by a thermal evaporation process, and may entirely cover the first to third organic light emitting layers EML1, EML2, and EML3.

In this process, the cathode electrode CE may be formed by a thermal evaporation process or a sputtering process, and may entirely cover the electron layer EITL.

Consequently, the display element layer 150 illustrated in FIG. 5 may be formed.

Referring to FIGS. 5 to 17 again, the display device 10 according to an embodiment may have fabrication easiness of an ultrahigh-resolution product in which an interval between the first to third light emitting elements ED1, ED2, and ED3 is narrow by forming the hole injection layer HIL, the hole transporting layer HTL, and the first to third organic light emitting layers EML1, EML2, and EML3 through the photo pattern process without using a separate fine metal mask (FMM).

In addition, the hole injection layer HIL and the hole transporting layer HTL included in the display device 10 according to an embodiment include the conductive high-molecular material robust against a high temperature, and accordingly, a material reliability defect due to the heat treatment process may be solved.

In addition, in the display device 10 according to an embodiment, the vacuum heat treatment process of about 150° C. or more is performed in the fabricating process, and accordingly, a reliability defect due to residual moisture included in the display device 10 may be solved.

The display device according to an embodiment of the present disclosure can be applied to various electronic devices. The electronic device according to the one embodiment of the present disclosure includes the display device described above, and may further include modules or devices having additional functions in addition to the display device.

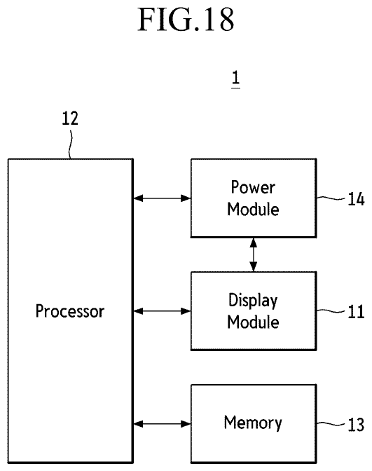

FIG. 18 is a block diagram of an electronic device according to an embodiment of the present disclosure.

Referring to FIG. 18, the electronic device 1 according to an embodiment of the present disclosure may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. In an embodiment, for example, the display device 10 may include the display module 11, and the processor 12, the memory 13, and the power module 14 may be provided in the form of other devices within the electronic device 11 other than the display device 10.

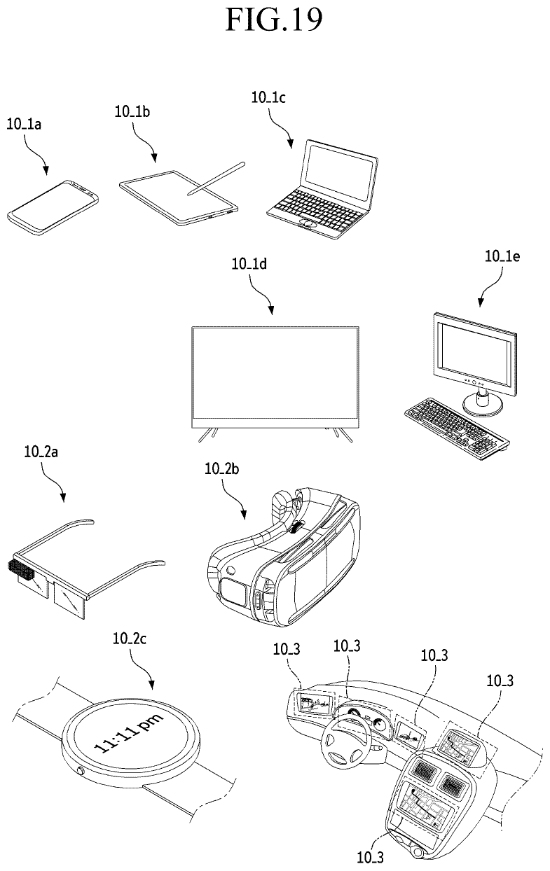

FIG. 19 is a schematic diagram of an electronic device according to various embodiments of the present disclosure.

Referring to FIG. 19, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a Center Information Display (CID) and a room mirror display arranged on a dashboard, center fascia, and dashboard of an automobile.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate on which an emission area and a non-emission area are defined;
a first anode electrode positioned on the substrate in the emission area;
a pixel defining layer positioned on the substrate in the non-emission area, defining an opening, and covering an edge of the first anode electrode;
a hole layer positioned on the first anode electrode;
a first organic light emitting layer positioned on the hole layer;
an electron layer positioned on the first organic light emitting layer;
a cathode electrode positioned on the electron layer,
wherein the hole layer includes a side surface facing the non-emission area, and
an inclination angle formed by the side surface of the hole layer and the pixel defining layer is in a range of about 60° to about 90°.

2. The display device of claim 1, wherein the hole layer includes a conductive high-molecular material.

3. The display device of claim 2, wherein the hole layer includes at least one selected from poly(3,4-ethylenedioxythiophene): poly(styrenesulfonate)(AI4083), tris(4-carbazoyl-9-ylphenyl)amine (TCTA), 4,4′-bis(N-carbazolyl)-1,1′-biphenyl (CBP), 2,2′,2″(1,3,5-benzinetriyl)-tris(1-phenyl-1-H-benzimidazole) (TPBI), and bis[2-(2-pyridinyl-N)phenyl-C](acetylacetonato) iridium(III) (Ir(ppy)₂(acac).

4. The display device of claim 1, wherein the hole layer includes:
a hole injection layer in contact with the first anode electrode, and
a hole transporting layer positioned between the injection layer and the first organic light emitting layer, and
an inclination angle formed by a side surface of the hole injection layer facing the non-emission area and the pixel defining layer is in the range of about 60° to about 90°.

5. The display device of claim 4, wherein an inclination angle formed by a side surface of the hole transporting layer facing the non-emission area and the hole injection layer is in the range of about 60° to about 90°.

6. The display device of claim 5, wherein an inclination angle formed by a side surface of the first organic light emitting layer facing the non-emission area and the hole transporting layer is in the range of about 60° to about 90°.

7. The display device of claim 6, wherein the electron layer is in contact and with and covers the side surface of the hole injection layer facing the non-emission area, the side surface of the hole transporting layer facing the non-emission area, and the side surface of the first organic light emitting layer facing the non-emission area.

8. The display device of claim 6, wherein the cathode electrode covers the side surface of the hole injection layer facing the non-emission area, the side surface of the hole transporting layer facing the non-emission area, and the side surface of the first organic light emitting layer facing the non-emission area.

9. The display device of claim 8, further comprising:
a second anode electrode spaced apart from the first anode electrode with the pixel defining layer interposed therebetween; and
a second organic light emitting layer positioned on the second anode electrode,
wherein the hole layer overlapping the first organic light emitting layer and the hole layer overlapping the second organic light emitting layer are spaced apart from each other with the pixel defining layer interposed therebetween.

10. The display device of claim 9, wherein the electronic layer is in contact with the first organic light emitting layer and the second organic light emitting layer, and
the electronic layer in contact with the first organic light emitting layer and the electronic layer in contact with the second organic light emitting layer are integral with each other, and
wherein the electronic layer includes a low-molecular material.

11. The display device of claim 9, wherein the pixel defining layer includes a first surface facing the cathode electrode,
the first surface includes:
a first portion overlapping the first organic light emitting layer;
a second portion overlapping the second organic light emitting layer; and
a third portion positioned between the first portion and the second portion, and
the third portion is covered by the electronic layer.
wherein the third portion is in entire contact with the electronic layer.

12. A method of fabricating a display device, the method comprising:
entirely coating a hole injection layer, a hole transporting layer, and an organic light emitting layer on a substrate including an anode electrode and a pixel defining layer;
removing portions of the hole injection layer, the hole transporting layer, and the organic light emitting layer by a photo pattern process;
removing moisture by performing a heat treatment at a temperature of about 150° C. or higher in a vacuum environment; and
entirely depositing an electronic layer and a cathode electrode on the organic light emitting layer.

13. The method of fabricating a display device of claim 12, wherein in the entire coating of the hole injection layer, the hole transporting layer, and the organic light emitting layer on the substrate including the anode electrode and the pixel defining layer, each of the hole injection layer and the hole transporting layer includes a conductive high-molecular material, and
the hole injection layer, the hole transporting layer, and the organic light emitting layer are exposed to the air.

14. The method of fabricating a display device of claim 12, wherein in the removing of the portions of the hole injection layer, the hole transporting layer, and the organic light emitting layer by the photo pattern process, the hole injection layer, the hole transporting layer, and the organic light emitting layer are simultaneously removed by a dry etching process, and, an inclination angle formed by the pixel defining layer and a side surface of the hole injection layer is in a range of about 60° to about 90°.

15. The method of fabricating a display device of claim 12, wherein in the entire depositing of the electronic layer and the cathode electrode on the organic light emitting layer,
the electron layer and the cathode electrode are deposited in a vacuum chamber, and
the electron layer includes a low-molecular material.

16. An electronic device comprising:
a display device comprising:
a substrate on which an emission area and a non-emission area are defined;
a first anode electrode positioned on the substrate in the emission area;
a pixel defining layer positioned on the substrate in the non-emission area, defining an opening, and covering an edge of the first anode electrode;
a hole layer positioned on the first anode electrode;
a first organic light emitting layer positioned on the hole layer;
an electron layer positioned on the first organic light emitting layer;
a cathode electrode positioned on the electron layer,
wherein the hole layer includes a side surface facing the non-emission area, and
an inclination angle formed by the side surface of the hole layer and the pixel defining layer is in a range of about 60° to about 90°.

17. The electronic device of claim 16, wherein the hole layer includes a conductive high-molecular material.

18. The electronic device of claim 17, wherein the hole layer includes at least one selected from poly(3,4-ethylenedioxythiophene): poly(styrenesulfonate)(AI4083), tris(4-carbazoyl-9-ylphenyl)amine (TCTA), 4,4′-bis(N-carbazolyl)-1,1′-biphenyl (CBP), 2,2′,2″(1,3,5-benzinetriyl)-tris(1-phenyl-1-H-benzimidazole) (TPBI), and bis[2-(2-pyridinyl-N)phenyl-C](acetylacetonato) iridium(III) (Ir(ppy)₂(acac).

19. The electronic device of claim 16, wherein the hole layer includes:
a hole injection layer in contact with the first anode electrode, and
a hole transporting layer positioned between the injection layer and the first organic light emitting layer, and
an inclination angle formed by a side surface of the hole injection layer facing the non-emission area and the pixel defining layer is in the range of about 60° to about 90°.

20. The electronic device of claim 19, wherein an inclination angle formed by a side surface of the hole transporting layer facing the non-emission area and the hole injection layer is in the range of about 60° to about 90°.
